(19) United States
(12) Patent Application Publication
(10) Pub. No.: US 2005/0023936 A1
(43) Pub. Date: Feb. 3, 2005

(54) Piezoelectric device

(75) Inventors: Tsuyoshi Futamata, Shinminato-shi (JP); Shigemasa Kusabiraki, Takaoka-shi (JP)

Correspondence Address: KEATING & BENNETT, LLP, 10400 EATON PLACE, SUITE 312, FAIRFAX, VA, 22030, US

(73) Assignee: Murata Manufacturing Co., Ltd., Nagaokakyo-shi (JP)

(21) Appl. No.: 10/849,449

(22) Filed: May 20, 2004

(30) Foreign Application Priority Data
Jul. 29, 2003 (JP) 2003-202836

(51) Int. Cl. H01L 41/053

(52) U.S. Cl. 310/348

(57) ABSTRACT

A piezoelectric device includes an elongated piezoelectric element including first internal electrodes and second internal electrodes extending along a direction that is substantially perpendicular to the length of the piezoelectric element and being arranged alternately along the length of the piezoelectric element, and first and second external electrodes provided on the bottom surface of the piezoelectric element. Bending vibration of the piezoelectric element occurs in a direction that is substantially perpendicular to the length of the piezoelectric element when an alternating voltage is applied between the first and second external electrodes. The piezoelectric device also includes supports that are attached to the bottom surface of the piezoelectric element at the upper ends thereof and bonded to a mounting board at the lower ends thereof, thereby supporting the piezoelectric element. The supports are made of a resin that does not have a glass transition point in an operating temperature range of the piezoelectric device.

### BACKGROUND OF THE INVENTION

1. Field of the Invention

The present invention relates to piezoelectric devices used as piezoelectric resonators and filters, and more specifically relates to a piezoelectric device using bending vibration of an elongated piezoelectric element.

2. Description of the Related Art

Piezoelectric devices using bending vibration in a direction perpendicular to the length of a piezoelectric element caused by a longitudinal piezoelectric effect are known in the art. Such a piezoelectric device is disclosed in, for example, Japanese Unexamined Patent Application Publication No. 2003-69372. FIG. 9 is a perspective view showing a process of mounting the piezoelectric device disclosed in the above-mentioned publication on a mounting board, and FIGS. 10A and 10B are a schematic side view and a schematic bottom view, respectively, of the piezoelectric device.

With reference to the figures, a piezoelectric device 101 includes an elongated piezoelectric element 102. The piezoelectric element 102 includes a plurality of first internal electrodes 103 and a plurality of second internal electrodes 104 which extend perpendicularly to the length of the piezoelectric element 102. In addition, the first internal electrodes 103 and the second internal electrodes 104 are alternately arranged along the length of the piezoelectric element 102.

Each of the first internal electrodes 103 includes a first electrode segment 103a and a second electrode segment 103b, which are separated from each other in a direction perpendicular to the length of the piezoelectric element 102. Piezoelectric layers are disposed between the first and second internal electrodes 103 and 104, and are alternately polarized in opposite directions along the length of the piezoelectric element 102. Accordingly, when an alternating voltage is applied between the first electrode segments 103a and the second electrode segments 103b of the internal electrodes 103, bending vibration of the piezoelectric element 102 occurs in the direction perpendicular to the length thereof.

The internal electrodes 103 and 104 are not shown in FIG. 10A. As shown in FIG. 10B, the piezoelectric element 102 also includes external electrodes 106 and 107 on the bottom surface 102a thereof. The external electrodes 106 and 107 are electrically connected to the second electrode segments 103b and the first electrode segments 103a, respectively.

A plurality of supports 108 to 111 are fixed on the bottom surface 102a of the piezoelectric element 102 such that they are electrically connected to the first and second external electrodes 106 and 107. The supports 108 to 111 are shaped like the letter ‘T’ when viewed from the direction perpendicular to the length of the piezoelectric element 102. The bottom ends of the supports 108 to 111 are bonded to electrode lands 122 and 123 provided on a mounting board 121. Thus, the piezoelectric device 101 is mounted on the mounting board 121.

The supports 108 to 111 are composed of a resin containing Ag particles. Accordingly, the supports 108 to 111 serve not only to fix and support the piezoelectric device 101 on the mounting board 121 but also to electrically connect the piezoelectric device 101 to the electrode lands 122 and 123 on the mounting board 121.

The ambient temperature at which the piezoelectric device 101 is operated varies with time, and the elasticity of the supports 108 to 111 included in the piezoelectric device 101 varies with the ambient temperature. Therefore, the characteristics of the piezoelectric device 101 are not stable.

### SUMMARY OF THE INVENTION

In order to overcome the above-described disadvantages and problems with the known piezoelectric devices, preferred embodiments of the present invention provide a high-reliability piezoelectric device including a piezoelectric element which uses a bending mode in a direction that is substantially perpendicular to the length thereof and having stable characteristics even when it is supported on amounting board and operated under varying ambient temperature conditions.

According to a preferred embodiment of the present invention, a piezoelectric device includes a piezoelectric element having first and second end surfaces on the longitudinal ends and a top surface, a bottom surface, and first and second side surfaces connecting the first and second end surfaces, the piezoelectric element including a plurality of piezoelectric layers and a plurality of internal electrodes, the internal electrodes extending substantially perpendicular to the length of the piezoelectric element and being arranged along the length of the piezoelectric element such that the internal electrodes face one another with the piezoelectric layers interposed therebetween, wherein bending vibration of the piezoelectric element occurs in a direction that is substantially perpendicular to the length of the piezoelectric element due to a longitudinal piezoelectric effect. The piezoelectric device also includes a plurality of supports which are fixed to the bottom surface of the piezoelectric element at the upper ends of the supports and to a mounting board at the lower ends of the supports, thereby supporting the piezoelectric element on the mounting board. The supports are composed of a resin that does not have a glass transition point Tg in an operating temperature range of the piezoelectric device.

According to preferred embodiments of the present invention, the resin may be a composite resin including conductive particles so that each of the supports is electrically connected to at least one of the internal electrodes.

In addition, according to a preferred embodiment of the present invention, the internal electrodes include first internal electrodes and second internal electrodes which are alternately arranged along the length of the piezoelectric element, each of the first internal electrodes including a first electrode segment and a second electrode segment which are separated from each other in the direction that is substantially perpendicular to the length of the piezoelectric element and which extend to the bottom surface of the piezoelectric element. In addition, the piezoelectric element may further include a first external electrode and a second external electrode on the bottom surface of the piezoelectric element, the first and second external electrodes being electrically connected to the first and second electrode segments, respectively, and at least two of the supports are fixed to each of the first and second external electrodes.

In addition, according to a preferred embodiment of the present invention, each of the supports may include an upper portion adjacent to the piezoelectric element and a lower portion remote from the piezoelectric element, the lower portion being thinner than the upper portion when viewed from the direction that is substantially perpendicular to the length of the piezoelectric element.

In addition, according to a preferred embodiment of the present invention, each of the supports may include an upper portion adjacent to the piezoelectric element and a lower portion remote from the piezoelectric element, the lower portion being thinner than the upper portion when viewed along the length of the piezoelectric element.

In the piezoelectric device according to a preferred embodiment of the present invention, the supports fixed to the piezoelectric element include a resin that does not have a glass transition point Tg in the operating temperature range of the piezoelectric device. Accordingly, when the piezoelectric device is operated while it is mounted on the mounting board with the supports, the elasticity of the supports does not suddenly change even then the ambient temperature varies within the operating temperature range. Thus, a piezoelectric device having stable characteristics in the operating temperature range is provided.

When the supports are composed of a material including conductive particles and serve not only to support the piezoelectric device on the mounting board but also to provide electrical connection, both the mechanical support and the electrical connection are provided by the supports. Therefore, the piezoelectric device can be easily mounted on the mounting board.

When the internal electrodes include the first internal electrodes and the second internal electrodes and each of the first internal electrodes includes the first electrode segment and the second electrode segment which are electrically connected to the first external electrode and the second external electrode, respectively, on the bottom surface of the piezoelectric element, bending vibration of the piezoelectric device is generated by applying an alternating voltage between the first and second external electrodes. When the supports fixed to the first and second external electrodes are composed of the composite resin including the conductive particles, the first and second external electrodes are electrically connected to electrode lands provided on the mounting board via the supports.

When each of the supports includes the upper portion and the lower portion and the lower portion is thinner than the upper portion when viewed from the direction that is substantially perpendicular to the length of the piezoelectric element, the width of the lower portion, which is restrained by the mounting board, is reduced without reducing the contact area between the piezoelectric element and the support. Accordingly, the frequency variation due to the temperature variation is more effectively suppressed.

Similarly, when the lower portion is thinner than the upper portion in each of the supports when viewed along the length of the piezoelectric element, the frequency variation due to the temperature variation is more effectively suppressed.

Other features, elements, characteristics and advantages of the present invention will become more apparent from the following detailed description of preferred embodiments thereof with reference to the attached drawings.

### BRIEF DESCRIPTION OF THE DRAWINGS

FIG. 1 is a perspective view showing a process of mounting a piezoelectric device according to a preferred embodiment of the present invention on a mounting board;

FIGS. 2A and 2B are cross sectional views of the piezoelectric device in FIG. 1, showing a first internal electrode and a second internal electrode, respectively, provided in the piezoelectric device;

FIGS. 3A and 3B are a schematic side view and a schematic bottom view, respectively, of the piezoelectric device in FIG. 1;

FIG. 4 is a graph of Young's modulus versus temperature for several kinds of resins including conductive particles;

FIG. 5 is a graph showing the relationship between the variation in resonant frequency and the temperature obtained when the piezoelectric device according to a preferred embodiment of the present invention and a piezoelectric device according to a comparative example are mounted on a mounting board;

FIG. 6 is a graph showing the relationship between the variation in resonant frequency and the support width of supports included in the piezoelectric device according to a preferred embodiment of the present invention;

FIG. 7 is a graph showing the relationship between the variation in resonant frequency and the temperature obtained when the support width is set to several different widths;

FIG. 8 is a bottom view showing vibration nodes of the piezoelectric device according to a preferred embodiment of the present invention in the mounted state;

FIG. 9 is a perspective view showing a process of mounting a known piezoelectric device on a mounting board; and

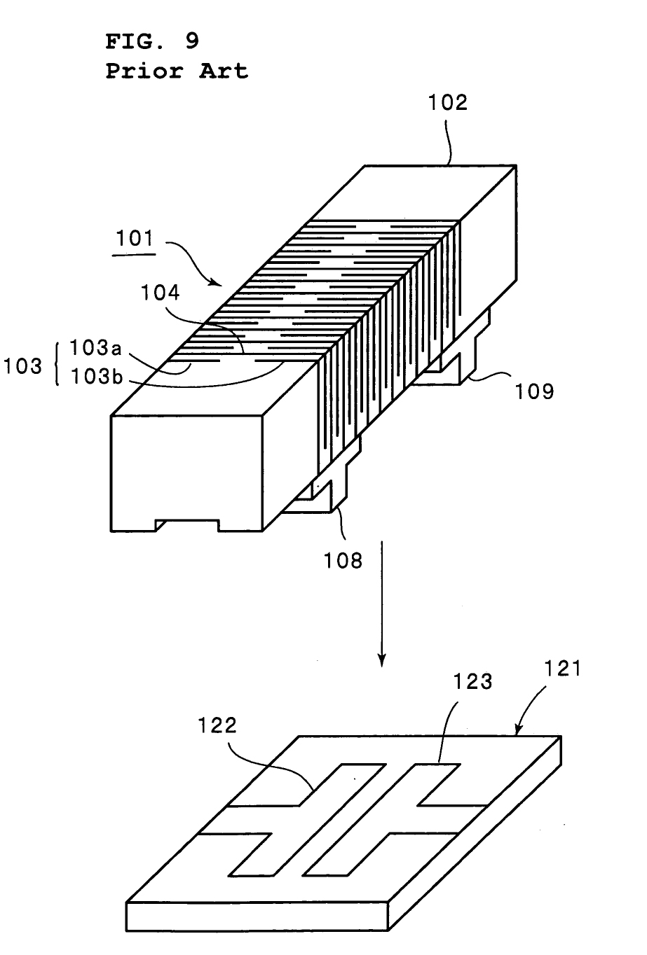

FIGS. 10A and 10B are a schematic side view and a schematic bottom view, respectively, of the known piezoelectric device.

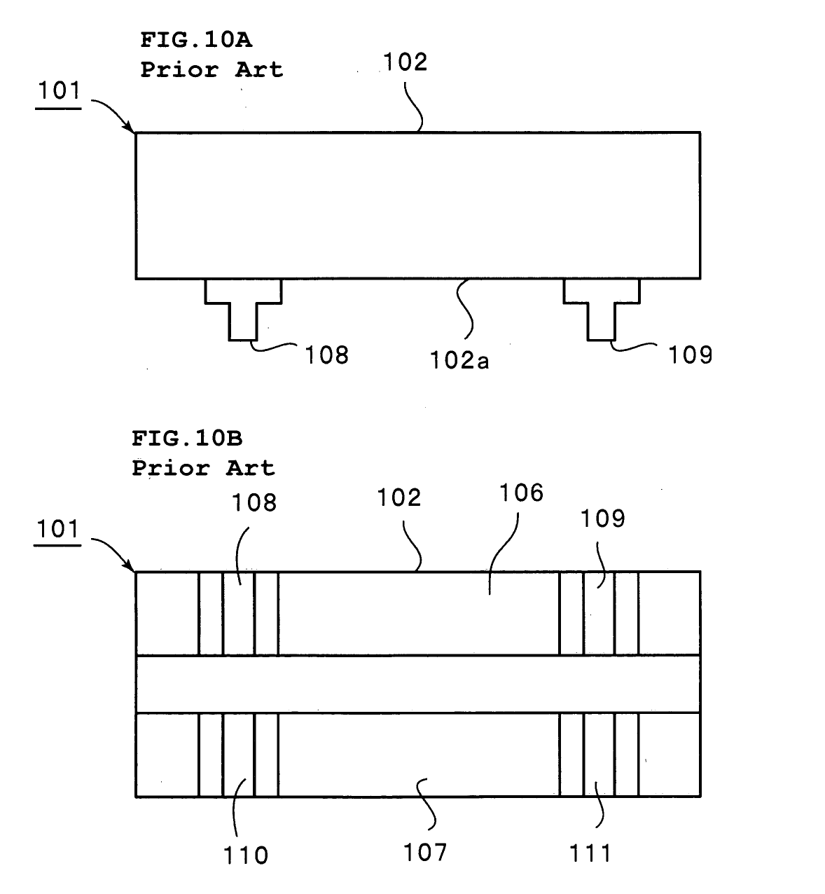

### DETAILED DESCRIPTION OF PREFERRED EMBODIMENTS

A preferred embodiment of the present invention will be described below with reference to the accompanying drawings.

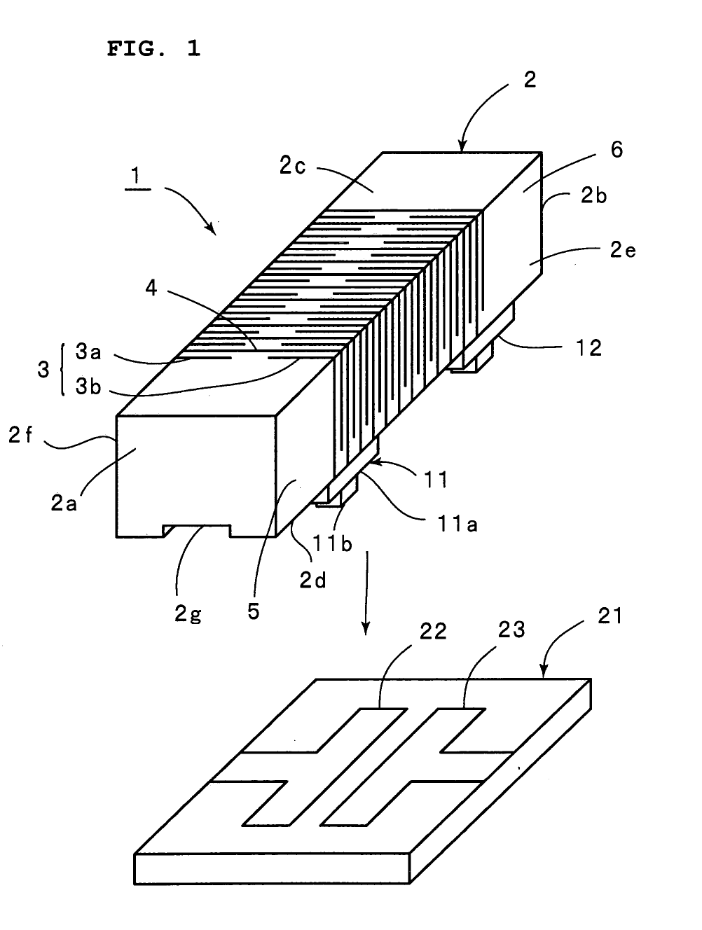

FIG. 1 is a perspective view showing a process of mounting a piezoelectric device 1 according to a preferred embodiment of the present invention on a mounting board 21.

The piezoelectric device 1 includes a piezoelectric element 2 having first and second end surfaces 2a and 2b, a top surface 2c, a bottom surface 2d, and first and second side surfaces 2e and 2f.

The piezoelectric element 2 includes a plurality of first internal electrodes 3 and a plurality of second internal electrodes 4, and the first and second internal electrodes 3 and 4 extend substantially perpendicular to the length of the piezoelectric element 2.

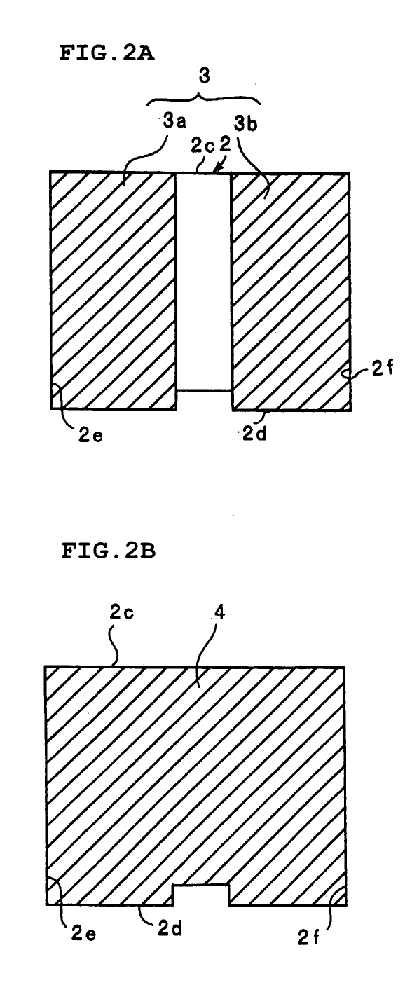

As shown in FIG. 2A, each of the first internal electrodes 3 has a first electrode segment 3a and a second electrode segment 3b. The first and second electrode segments 3a and 3b extend to the bottom surface 2d of the piezoelectric element 2.

The second internal electrodes 4 are not segmented, and are arranged so as to face the first and second electrode segments 3a and 3b with piezoelectric layers disposed therebetween. The second internal electrodes 4 do not extend to the bottom surface 2d of the piezoelectric element 2.

With reference to FIG. 1 again, the piezoelectric layers disposed between the first and second internal electrodes 3 and 4 in the piezoelectric element 2 are polarized along the length of the piezoelectric element 2 such that the polarization directions of the adjacent piezoelectric layers are opposite to each other.

In addition, inert layers 5 and 6, which are spaced from the internal electrodes 3 and 4, are provided on the ends of the piezoelectric element 2.

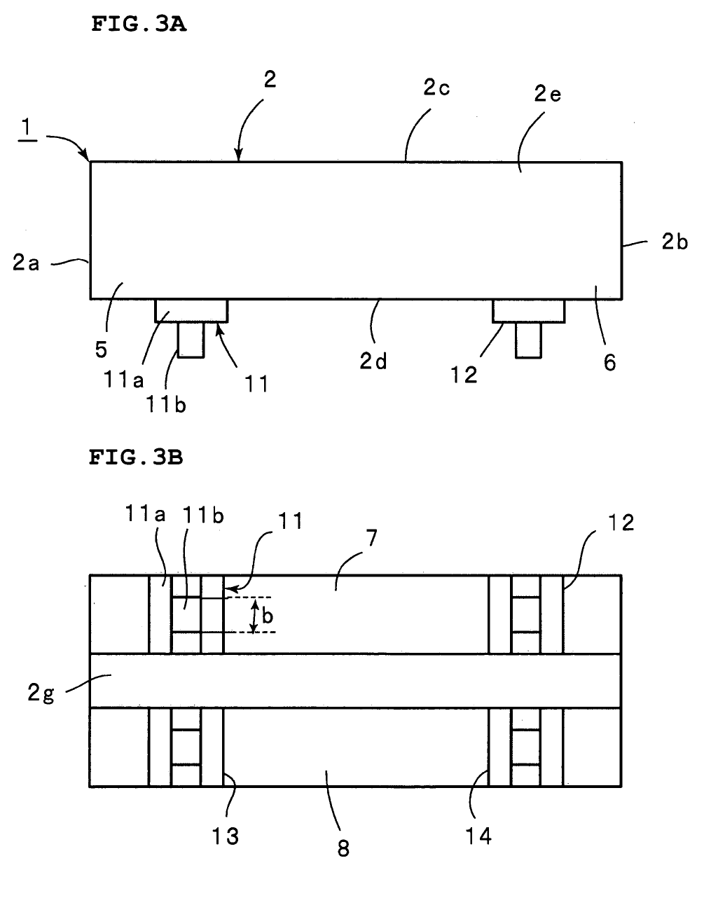

FIGS. 3A and 3B are a schematic side view and a schematic bottom view, respectively, of the piezoelectric device 1. The internal electrodes 3 and 4 are not shown in FIG. 3A. As shown in FIG. 3B, the piezoelectric element 2 is provided with a slit 2g which extends along the length of the piezoelectric element 2 in the bottom surface 2d thereof, and first and second external electrodes 7 and 8 are provided on the sides of the slit 2g. The first external electrode 7 is electrically connected to the first electrode segments 3a, and the second external electrode 8 is electrically connected to the second electrode segments 3b.

Thus, the piezoelectric element 2 is constructed of the first and second internal electrodes 3 and 4, the piezoelectric layers interposed therebetween, the inert layers 5 and 6, and the first and second external electrodes 7 and 8. When an alternating voltage is applied between the first and second external electrodes 7 and 8, bending vibration of the piezoelectric element 2 occurs in the direction that is substantially perpendicular to its length.

The piezoelectric layers are preferably made of, for example, a piezoelectric ceramic such as a lead zirconate titanate ceramic or other suitable material. In addition, the internal electrodes 3 and 4 and the external electrodes 7 and 8 are preferably made of a suitable conductive material such as Ag and Ag-Pd.

The inert layers 5 and 6 are preferably made of the same piezoelectric material as that of the piezoelectric layers. However, the inert layers 5 and 6 may also be made of another ceramic material such as alumina. In the present preferred embodiment, the piezoelectric element 2 is constructed by co-firing of an electrode material and a ceramic.

In the piezoelectric device 1 according to the present preferred embodiment, a plurality of supports 11 to 14 are fixed on the bottom surface 2d of the piezoelectric element 2, and the supports 11 to 14 are preferably made of a resin that does not have a glass transition point Tg in an operating temperature range of the piezoelectric device 1.

The piezoelectric device 1 is mounted on the mounting board 21 shown in the lower portion of FIG. 1 by attaching the supports 11 to 14 to electrode lands 22 and 23 provided on the mounting board 21.

As described above, the supports 11 to 14 are preferably made of a resin that does not have a glass transition point Tg in the operating temperature range. The operating temperature range is, for example, about −30° C. to about +85° C., and is defined as a temperature range in which the operation of the piezoelectric device 1 is ensured.

The supports 11 to 14 may be made of various synthetic resins. In the present preferred embodiment, since the supports 11 to 14 electrically connect the first and second external electrodes 7 and 8 to the electrode lands 23 and 22, respectively, the supports 11 to 14 are preferably made of a conductive composite resin obtained by adding a conductive material, such as Ag particles, in a resin. In addition, in the present preferred embodiment, the glass transition point Tg of this composite resin is outside the operating temperature range.

If the glass transition point Tg of the resin forming the supports 11 to 14 is within the operating temperature range, the elasticity of the supports 11 to 14 greatly varies depending on whether the temperature is above or below the glass transition point Tg. Accordingly, the characteristics of the piezoelectric device 1 also greatly vary depending on whether the temperature is above or below the glass transition point Tg.

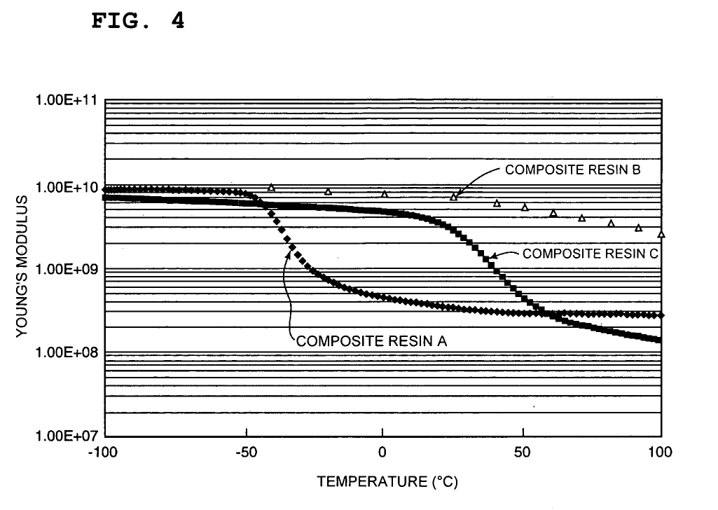

In comparison, according to the present preferred embodiment, the glass transition point Tg is outside the operating temperature range. Therefore, the elasticity of the supports 11 to 14 varies only slightly in the operating temperature range. Accordingly, the characteristics are maintained stable irrespective of the temperature variation. This will be described in more detail below with reference to FIG. 4.

FIG. 4 is a graph of Young's modulus (Pa) versus temperature for several kinds of resins containing about 80% to about 83% by weight of Ag particles as conductive particles. With respect to the values on the vertical axis of the graph shown in FIG. 4, 1.00E+09, for example, means 1.00×10⁺⁹. As is clear from FIG. 4, the Young's modulus of a composite resin A, which is obtained by adding the conductive particles to urethane resin (polyester polyol resin, the glass transition point Tg is about −40° C.), greatly decreases at around about −40° C. but varies only slightly when the temperature is in the range of about −30° C. to about +100° C.

In addition, the Young's modulus of a composite resin B, which is obtained by adding the conductive particles to epoxy resin (dimer acid modified epoxy, the glass transition point Tg is about 120° C.), gradually decreases but does not change suddenly when the temperature is in the range of about −50° C. to about +100° C.

In contrast, the Young's modulus of a composite resin C, which is obtained by adding the conductive particles to epoxy resin (phenolic epoxy, the glass transition point Tg is about 45° C.), greatly varies when the temperature is in the range of about +30° C. to about 50° C.

As is clear from FIG. 4, in the case in which the supports 11 to 14 are made of a composite resin obtained by adding conductive particles to a resin, the Young's modulus varies only slightly while the temperature is in the actual operating temperature range, that is, about −30° C. to about 100° C., if the glass transition point Tg of the composite resin is outside this temperature range.

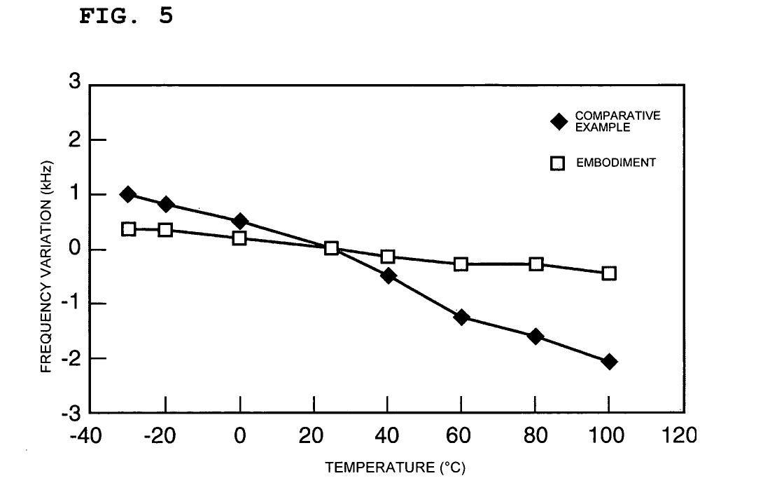

As an example, a piezoelectric device identical to the piezoelectric device 1 according to the above-described preferred embodiment was manufactured. In the manufactured piezoelectric device, the supports 11 to 14 were made of the composite resin B obtained by adding the conductive particles to epoxy resin having a glass transition point Tg of about 120° C. The length, width, and thickness of the piezoelectric element 2 were approximately 2 mm, 0.52 mm, and 0.42 mm, respectively, and the center frequency was about 450 kHz. The distance between the centers of the supports 11 and 12 and that between the centers of the supports 13 and 14 were about 1.3 mm, and the slit width was about 0.15 mm. This piezoelectric device was mounted on a mounting board with a conductive adhesive, and variation in the resonant frequency caused by temperature variation was determined. The result is shown in FIG. 5.

For the purpose of comparison, a piezoelectric device that is similar to the piezoelectric device 1 according to the above-described preferred embodiment except for the material of the supports 11 to 14 was manufactured as a comparative example. In this piezoelectric device, the supports were made of the composite resin C shown in FIG. 4, which is obtained by adding the conductive particles to epoxy resin having a glass transition point Tg of about 45° C. This piezoelectric device was also mounted on a mounting board with a conductive adhesive, and variation in the resonant frequency caused by temperature variation was determined. The result is shown in FIG. 5.

In FIG. 5, the frequency variation (kHz) on the vertical axis shows the variation in the resonant frequency (kHz) from that at about +25° C.

As is clear from FIG. 5, in the piezoelectric device according to the present preferred embodiment in which the supports are made of the composite resin B, whose glass transition point Tg is outside the operating temperature range, the variation in the resonant frequency is extremely small in the temperature range of about −30° C. to about +100° C. In contrast, in the piezoelectric device according to the comparative example in which the supports are composed of the composite resin C, the resonant frequency greatly decreases as the temperature increases in the range of about −30° C. to about +100° C.

In the piezoelectric device 1 according to the above-described preferred embodiment, each of supports 11 to 14 includes an upper portion adjacent to the piezoelectric element 2 and a lower portion remote from the piezoelectric element 2, and the lower portion is thinner than the upper portion. In other words, in each of the supports 11 to 14, the dimension of the lower portion in the direction that is substantially perpendicular to the side surfaces 2e and 2f is smaller than that of the upper portion which is bonded to the bottom surface 2d of the image plane 2. More specifically, as shown in FIGS. 3A and 3B, the support 11, for example, includes a plate-shaped base portion 11a fixed to the piezoelectric element 2 and an end portion 11b extending downward from the base portion 11a.

The bottom end of the end portion 11b is bonded to the electrode land 23 on the mounting board 21. The dimension of the end portion 11b in the direction that is substantially perpendicular to the side surfaces 2e and 2f at the bottom end thereof is defined as a support width b. Piezoelectric devices having various support widths b were manufactured to determine the influence of the support width b on the resonant frequency.

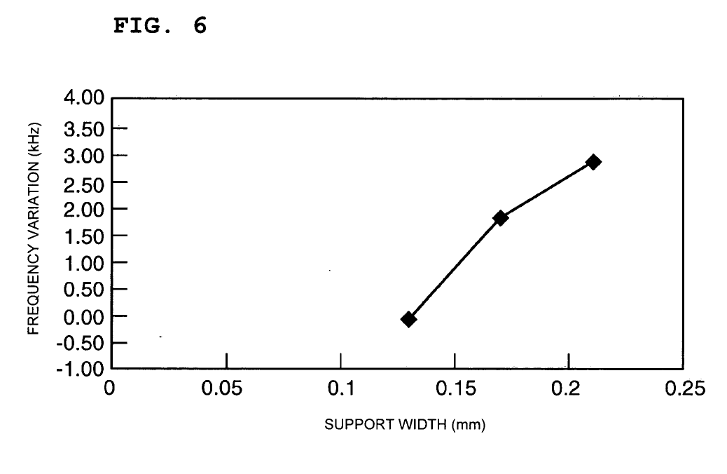

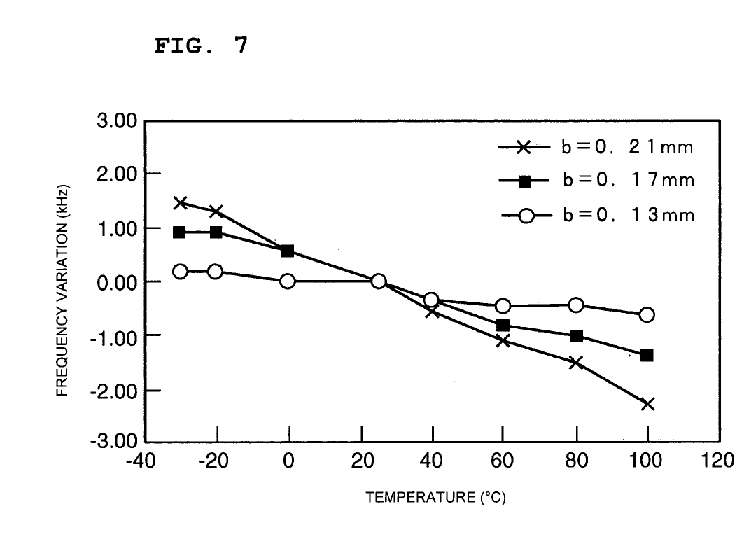

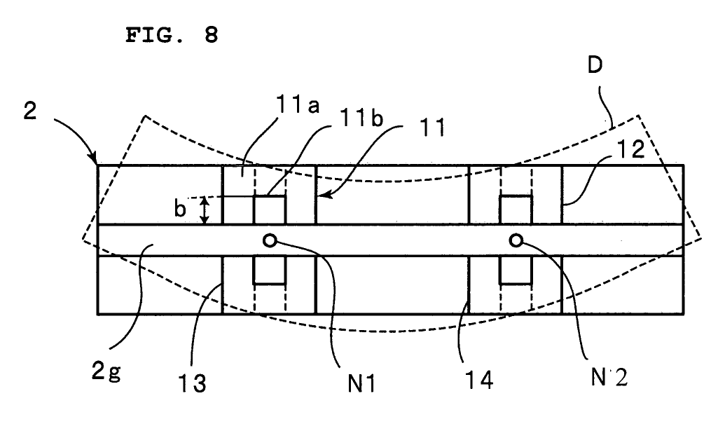

The manufactured piezoelectric devices were mounted such that the inner side of the end portion 11b in the width direction of the piezoelectric element 2 was in contact with the slit 2g, as shown in FIG. 8, and end portions of the other supports 12 to 14 were arranged in a similar manner. The result is shown in FIGS. 6 and 7. FIG. 6 is a graph showing the relationship between the variation in resonant frequency and the support width b, and FIG. 7 is a graph showing the relationship between the variation in resonant frequency and the temperature for several different support widths b.

As is clear from FIG. 6, the resonant frequency increases as the support width b increases. This is because vibration nodes N1 and N2 of the piezoelectric device 1 are positioned between the supports 11 and 13 and between the supports 12 and 14, respectively, on the longitudinal center line of the piezoelectric element 2, as shown in FIG. 8 (bottom view), and the supports 11 to 14 are arranged on both sides of the nodes N1 and N2. More specifically, since the supports 11 to 14 are arranged near the nodes N1 and N2 and bending vibration of the piezoelectric element 2 occurs in the direction that is substantially perpendicular to the length of the piezoelectric element 2, the vibration amplitude decreases and the resonant frequency increases as the support width b increases. The broken line D in FIG. 8 shows a position of the piezoelectric element 2 in the bending vibration.

Accordingly, in the piezoelectric device 1 according to the present preferred embodiment, the resonant frequency can be finely adjusted by changing the support width b of the above-described supports 11 to 14.

In addition, as is clear from FIG. 7, when the support width b is varied between about 0.21 mm, about 0.17 mm, and about 0.13 mm, the manner in which the frequency varies with the temperature also changes. More specifically, the frequency variation caused by the temperature variation decreases as the support width b decreases. Thus, according to various preferred embodiments of the present invention, the stability of the characteristics relative to the temperature variation and the resonant frequency can be adjusted by changing the support width b of the supports 11 to 14.

While the present invention has been described with respect to preferred embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

1. A piezoelectric device comprising:
a piezoelectric element having first and second end surfaces on longitudinal ends and a top surface, a bottom surface, and first and second side surfaces connecting the first and second end surfaces, the piezoelectric element including a plurality of piezoelectric layers and a plurality of internal electrodes, the internal electrodes extending substantially perpendicular to the length of the piezoelectric element and being arranged along the length of the piezoelectric element such that the internal electrodes face one another with the piezoelectric layers interposed therebetween, wherein bending vibration of the piezoelectric element occurs in a direction that is substantially perpendicular to the length of the piezoelectric element due to a longitudinal piezoelectric effect; and
a plurality of supports fixed to the bottom surface of the piezoelectric element at upper ends of the supports and to a mounting board at lower ends of the supports, thereby supporting the piezoelectric element on the mounting board; wherein
the supports include a resin which does not have a glass transition point Tg in an operating temperature range of the piezoelectric device.

2. A piezoelectric device according to claim 1, wherein the resin is a composite resin including conductive particles and each of the supports is electrically connected to at least one of the internal electrodes.

3. A piezoelectric device according to claim 2, wherein the internal electrodes include first internal electrodes and second internal electrodes which are alternately arranged along the length of the piezoelectric element, each of the first internal electrodes including a first electrode segment and a second electrode segment which are separated from each other in the direction that is substantially perpendicular to the length of the piezoelectric element and which extend to the bottom surface of the piezoelectric element, and the piezoelectric element further includes a first external electrode and a second external electrode on the bottom surface of the piezoelectric element, the first and second external electrodes being electrically connected to the first and second electrode segments, respectively, and at least two of the supports are fixed to each of the first and second external electrodes.

4. A piezoelectric device according to claim 1, wherein each of the supports includes an upper portion adjacent to the piezoelectric element and a lower portion remote from the piezoelectric element, the lower portion being thinner than the upper portion when viewed from the direction that is substantially perpendicular to the length of the piezoelectric element.

5. A piezoelectric device according to claim 2, wherein each of the supports includes an upper portion adjacent to the piezoelectric element and a lower portion remote from the piezoelectric element, the lower portion being thinner than the upper portion when viewed from the direction that is substantially perpendicular to the length of the piezoelectric element.

6. A piezoelectric device according to claim 3, wherein each of the supports includes an upper portion adjacent to the piezoelectric element and a lower portion remote from the piezoelectric element, the lower portion being thinner than the upper portion when viewed from the direction that is substantially perpendicular to the length of the piezoelectric element.

7. A piezoelectric device according to claim 1, wherein each of the supports includes an upper portion adjacent to the piezoelectric element and a lower portion remote from the piezoelectric element, the lower portion being thinner than the upper portion when viewed along the length of the piezoelectric element.

8. A piezoelectric device according to claim 2, wherein each of the supports includes an upper portion adjacent to the piezoelectric element and a lower portion remote from the piezoelectric element, the lower portion being thinner than the upper portion when viewed along the length of the piezoelectric element.

9. A piezoelectric device according to claim 3, wherein each of the supports includes an upper portion adjacent to the piezoelectric element and a lower portion remote from the piezoelectric element, the lower portion being thinner than the upper portion when viewed along the length of the piezoelectric element.

10. A piezoelectric device according to claim 4, wherein the lower portion is thinner than the upper portion when viewed along the length of the piezoelectric element.

11. A piezoelectric device according to claim 1, wherein nodes of the piezoelectric element are located between the supports.

12. A piezoelectric device according to claim 3, wherein the second internal electrodes are spaced from the bottom surface of the piezoelectric element.

13. A piezoelectric device according to claim 1, wherein the piezoelectric layers are polarized along the length of piezoelectric element and adjacent pairs of the piezoelectric layers are polarized in opposite directions.

14. A piezoelectric device according to claim 1, further comprising inert layers disposed on the ends of the piezoelectric element and spaced from the internal electrodes.

15. A piezoelectric device according to claim 1, wherein the piezoelectric element includes a slit that extends along the length of the piezoelectric element.

16. A piezoelectric device according to claim 1, wherein the supports are made of a conductive composite resin.

17. A piezoelectric device comprising:
a piezoelectric element having first and second end surfaces on longitudinal ends and a top surface, a bottom surface, and first and second side surfaces connecting the first and second end surfaces, the piezoelectric element including a plurality of piezoelectric layers and a plurality of internal electrodes, the internal electrodes extending substantially perpendicular to the length of the piezoelectric element and being arranged along the length of the piezoelectric element such that the internal electrodes face one another with the piezoelectric layers interposed therebetween, wherein bending vibration of the piezoelectric element occurs in a direction that is substantially perpendicular to the length of the piezoelectric element due to a longitudinal piezoelectric effect; and
a plurality of supports fixed to the bottom surface of the piezoelectric element at upper ends of the supports and to a mounting board at lower ends of the supports, thereby supporting the piezoelectric element on the mounting board; wherein
the supports include a resin which does not have a glass transition point Tg in an operating temperature range of about −30° C. to about +85° C.

18. A piezoelectric device according to claim 17, wherein the resin is a composite resin including conductive particles and each of the supports is electrically connected to at least one of the internal electrodes.

19. A piezoelectric device according to claim 18, wherein the internal electrodes include first internal electrodes and second internal electrodes which are alternately arranged along the length of the piezoelectric element, each of the first internal electrodes including a first electrode segment and a second electrode segment which are separated from each other in the direction that is substantially perpendicular to the length of the piezoelectric element and which extend to the bottom surface of the piezoelectric element, and the piezoelectric element further includes a first external electrode and a second external electrode on the bottom surface of the piezoelectric element, the first and second external electrodes being electrically connected to the first and second electrode segments, respectively, and at least two of the supports are fixed to each of the first and second external electrodes.

20. A piezoelectric device according to claim 17, wherein each of the supports includes an upper portion adjacent to the piezoelectric element and a lower portion remote from the piezoelectric element, the lower portion being thinner than the upper portion when viewed from the direction that is substantially perpendicular to the length of the piezoelectric element.
